(19) United States
(12) Patent Application Publication
(10) Pub. No.: US 2024/0079848 A1
(43) Pub. Date: Mar. 7, 2024

(54) OPTICAL MODULE

(71) Applicant: Sumitomo Electric Industries, Ltd., Osaka-shi, Osaka (JP)

(72) Inventor: Hiromi NAKANISHI, Osaka-shi, Osaka (JP)

(73) Assignee: Sumitomo Electric Industries, Ltd., Osaka-shi, Osaka (JP)

(21) Appl. No.: 18/271,053

(22) PCT Filed: Oct. 26, 2021
(86) PCT No.: PCT/JP2021/039394

§ 371 Date: Jul. 6, 2023

(30) Foreign Application Priority Data
Jan. 18, 2021 (JP) 2021-005725

(51) Int. Cl. H01S 5/0239; G02B 26/10; H01S 5/02253

(52) U.S. Cl. CPC H01S 5/0239; G02B 26/105; H01S 5/02253

(57) ABSTRACT

An optical module includes a base member including a first surface, a first semiconductor light-emitting element mounted on the first surface and configured to emit first light having a first wavelength, a first filter mounted on the first surface and including a first reflection surface configured to reflect the first light, a second semiconductor light-emitting element mounted on the first surface and configured to emit second light having a second wavelength differing from the first wavelength, and a second filter mounted on the first surface and including a second reflection surface configured to reflect the second light.

### TECHNICAL FIELD

The present disclosure relates to an optical module. This application claims priority based on Japanese Patent Application No. 2021-005725 filed on Jan. 18, 2021, and the entire contents of the Japanese patent application are incorporated herein by reference.

### BACKGROUND

Optical modules comprising light-emitting elements are known (see for example PTL 1). The optical module disclosed in PTL 1 includes a wavelength selection filter that directly receives light from a light-emitting element and selects a wavelength.

### PRIOR ART DOCUMENT

### Patent Literature

PTL 1: Japanese Unexamined Patent Application Publication No. 2009-93101

### SUMMARY

An optical module according to one aspect of the present disclosure includes a base member including a first surface, a first semiconductor light-emitting element mounted on the first surface and configured to emit first light having a first wavelength, a first filter mounted on the first surface and including a first reflection surface configured to reflect the first light, a second semiconductor light-emitting element mounted on the first surface and configured to emit second light having a second wavelength differing from the first wavelength, and a second filter mounted on the first surface and including a second reflection surface configured to reflect the second light. The first light and the second light are multiplexed when the first light reflected by the first reflection surface passes through the second filter and the second reflection surface reflects the second light. A length of the first filter differs from a length of the second filter in a direction perpendicular to the first surface.

An optical module according to another aspect of the present disclosure includes a base member including a first surface, a first semiconductor light-emitting element mounted on the first surface and configured to emit first light having a first wavelength, a first filter mounted on the first surface and including a first reflection surface configured to reflect the first light, a second semiconductor light-emitting element mounted on the first surface and configured to emit second light having a second wavelength differing from the first wavelength, a second filter mounted on the first surface and including a second reflection surface configured to reflect the second light, a third semiconductor light-emitting element mounted on the first surface and configured to emit third light having a third wavelength differing from the first wavelength and the second wavelength, and a second filter mounted on the first surface and including a third reflection surface configured to reflect the third light. When viewed in a direction perpendicular to the first surface, the first filter is disposed between the second filter and the third filter. The first light, the second light, and the third light are multiplexed when the first light reflected by the first reflection surface passes through the second filter, the second reflection surface reflects the second light, and the third light reflected by the third reflection surface passes through the first filter and the second filter. In the direction perpendicular to the first surface, a length of the first filter is longer than a length of the second filter and a length of the third filter.

### BRIEF DESCRIPTION OF THE DRAWINGS

FIG. 1 is a schematic side view showing an appearance of an optical module according to a first embodiment.

FIG. 2 is a schematic side view of the optical module shown in FIG. 1 with the cap removed.

FIG. 3 is a schematic plan view of the optical module shown in FIG. 2.

FIG. 4 is an enlarged view showing a part of the optical module shown in FIG. 3.

FIG. 5 is a schematic plan view showing an enlarged part of the optical module according to the second embodiment.

FIG. 6 is a schematic perspective view showing an enlarged part of the optical module according to the third embodiment.

FIG. 7 is a schematic plan view of the optical module shown in FIG. 6 cut along a plane including the cap.

FIG. 8 is a schematic perspective view of the optical module according to the fourth embodiment.

FIG. 9 is a schematic perspective view of the optical module shown in FIG. 8 with the cap removed.

FIG. 10 is a schematic plan view when the optical module shown in FIG. 8 is cut along a plane including the cap.

### DETAILED DESCRIPTION

### Problems to be Solved by Present Disclosure

An optical module including a plurality of semiconductor light-emitting elements and a filter that multiplexes light emitted from the plurality of semiconductor light-emitting elements can emit light in which light having different wavelengths is multiplexed. In optical modules, miniaturization has been required in recent years. In order to realize the miniaturization of the optical module, it is necessary to realize the miniaturization of each component constituting the optical module. At the time of manufacturing the optical module, it is necessary to accurately dispose the miniaturized components. However, in the optical module disclosed in PTL 1, it may be difficult to cope with minimization.

Therefore, one of the objectives is to provide an optical module which can be easily miniaturized.

### Advantageous Effects of Present Disclosure

According to the optical module, miniaturization can be easily realized.

### Description of Embodiments of Present Disclosure

First, embodiments of the present disclosure will be listed and explained.

(1) An optical module according to one aspect of present disclosure includes a base member including a first surface, a first semiconductor light-emitting element mounted on the first surface and configured to emit first light having a first wavelength, a first filter mounted on the first surface and including a first reflection surface configured to reflect the first light, a second semiconductor light-emitting element mounted on the first surface and configured to emit second light having a second wavelength differing from the first wavelength, and a second filter mounted on the first surface and including a second reflection surface configured to reflect the second light. The first light and the second light are multiplexed when the first light reflected by the first reflection surface passes through the second filter and the second reflection surface reflects the second light. A length of the first filter differs from a length of the second filter in a direction perpendicular to the first surface.

In the optical module, a first semiconductor light-emitting element, a second semiconductor light-emitting element, a first filter, and a second filter are mounted on a first surface of a base member. As an example of a method of manufacturing a optical module, for example, a first semiconductor light-emitting element and a second semiconductor light-emitting element are mounted on a first surface of a base member, and then a first filter and a second filter are mounted on the first surface of the base member. At this time, the first filter and the second filter are adhered to the first surface using an adhesive coated on the first surface. Further, the first filter and the second filter are mounted on the first surface in consideration of the emitting direction of the first light emitted from the first semiconductor light-emitting element, the emitting direction of the second light emitted from the second semiconductor light-emitting element, and the like. Specifically, one of the first filter and the second filter is first grasped by using a jig such as tweezers for grasping the filter, and is mounted on the first surface of the base member so as to be placed from above the base member. Next, after the jig is removed from the filter, another filter is grasped by the jig and mounted on the first surface so as to be placed from above the base member. Here, when the miniaturization of the optical module proceeds, the interval between the first filter and the second filter becomes narrower as the miniaturization of each component constituting the optical module proceeds. Then, when the filter to be mounted later is attached and the jig is removed, there is a possibility that the previously mounted filter and the jig interfere with each other. As a result, there is a possibility that the position of the previously mounted filter is shifted or the previously mounted filter is damaged.

According to the optical module of the present disclosure, in a direction perpendicular to the first surface, the length of the first filter differs from the length of the second filter. In such an optical module, the first filter or the second filter, whichever has the shorter length, is first pinched and grasped by the above jig, the position is adjusted and mounted at the desired position on the first surface. Next, the filter having the longer length is pinched and grasped by the jig, its position is adjusted and mounted at the desired position on the first surface. After mounting, when the jig is removed from the filter, since the length of the filter mounted later is longer than the length of the filter mounted previously, the possibility of interference between the filter mounted previously and the jig can be greatly reduced. Therefore, when the filter is mounted later, it is possible to greatly reduce the possibility that the previously mounted filter and the jig come into contact with each other and the position of the previously mounted filter is shifted or damaged. Therefore, it is possible to reduce labor at the time of manufacturing each miniaturized component which requires careful work at the time of mounting the filter later. As a result, according to such an optical module, miniaturization can be easily achieved.

(2) In the above optical module, the first reflection surface may be located outside an optical path of at least either one of light emitted from the second semiconductor light-emitting element and passing through the second filter and light emitted from the first semiconductor light-emitting element and reflected by the second filter. With respect to the second light, in the second filter, there is light that is not reflected by the second reflection surface but a part of the second light passes through the second filter although it is a small amount. In addition, regarding the first light, in the second filter, there is light in which the first light is partially reflected in a portion which is not the second reflection surface although it is a small amount. When the partially passed second light or the partially reflected first light reaches the first reflection surface of the first filter and is reflected, it may become stray light having the same emission direction as the multiplexed light. Such a situation is undesirable because stray light may be emitted to the outside of the optical module.

According to the above optical module, the first reflection surface is located outside an optical path of at least either one of light emitted from the second semiconductor light-emitting element and passing through the second filter and light emitted from the first semiconductor light-emitting element and reflected by the second filter. Therefore, it is possible to reduce the possibility that the second light emitted from the second semiconductor light-emitting element and passing through the second filter without being reflected by the second reflection surface and the first light emitted from the first semiconductor light-emitting element and reflected by a portion other than the second reflection surface of the second filter reach the first reflection surface. Then, it is possible to reduce the possibility that the second light passing through the second filter and the first light reflected by the second filter are reflected by the first reflection surface and become stray light. As a result, it is possible to reduce the possibility that stray light is emitted to the outside of the optical module.

(3) In the above optical module, an interval between the first filter and the second filter may be 0.1 mm to 0.3 mm. Such an optical module can reliably realize miniaturization.

(4) The optical module may further include a lens configured to change a spot size of the first light emitted from the first semiconductor light-emitting element or the second light emitted from the second semiconductor light-emitting element. In this way, first light or second light having a desired spot size can be emitted from the optical module.

(5) The optical module may further include a mirror drive mechanism including a mirror configured to reflect light multiplexed by the second filter, the mirror drive mechanism being configured to scan and emit the light multiplexed by the second filter. Such an optical module can draw characters, figures, and the like by scanning light obtained by multiplexing the first light and the second light along a desired path.

(6) In the optical module, the first filter and the second filter each may have a plate shape. When viewed in the direction perpendicular to the first surface, a length of the first filter in a direction perpendicular to a thickness direction of the first filter may be shorter than a length of the second filter in a direction perpendicular to a thickness direction of the second filter. In this way, it is easy to locate the first reflection surface outside the optical path of at least either one of the light emitted from the second semiconductor light-emitting element and passing through the second filter and the light emitted from the first semiconductor light-emitting element and reflected by the second filter. Therefore, it becomes easy to reduce the possibility of occurrence of stray light.

(7) An optical module according to another aspect of the present disclosure includes a base member including a first surface, a first semiconductor light-emitting element mounted on the first surface and configured to emit first light having a first wavelength, a first filter mounted on the first surface and including a first reflection surface configured to reflect the first light, a second semiconductor light-emitting element mounted on the first surface and configured to emit second light having a second wavelength differing from the first wavelength, a second filter mounted on the first surface and including a second reflection surface configured to reflect the second light, a third semiconductor light-emitting element mounted on the first surface and configured to emit third light having a third wavelength differing from the first wavelength and the second wavelength, and a second filter mounted on the first surface and including a third reflection surface configured to reflect the third light. When viewed in a direction perpendicular to the first surface, the first filter is disposed between the second filter and the third filter. The first light, the second light, and the third light are multiplexed when the first light reflected by the first reflection surface passes through the second filter, the second reflection surface reflects the second light, and the third light reflected by the third reflection surface passes through the first filter and the second filter. In the direction perpendicular to the first surface, a length of the first filter is longer than a length of the second filter and a length of the third filter.

In the manufacture of an optical module according to another embodiment of the present disclosure, a filter having a length shorter than the length of the first filter, i.e., either the second filter or the third filter, is pinched and grasped by the jig in a direction perpendicular to the first surface, the position is adjusted and mounted at a desired position on the first surface. Next, another filter having a length shorter than the length of the first filter is pinched and grasped, and the position thereof is adjusted and mounted at a desired position on the first surface. When the jig is removed from the filter mounted later, the interval between the second filter and the third filter is relatively large, so that the possibility of interference between the filter mounted previously and the jig can be greatly reduced. Next, in a direction perpendicular to the first surface, the filter having the longest length, i.e., the first filter, is pinched and grasped by the jig, and the position thereof is adjusted and mounted at a desired position on the first surface. After mounting, when the jig is removed from the first filter, since the length of the first filter mounted later is longer than the lengths of the second filter and the third filter mounted previously, the possibility of interference between the second filter and the third filter and the jig can be greatly reduced. Therefore, when the first filter is mounted, it is possible to greatly reduce the possibility that the second filter or the third filter mounted previously comes into contact with the jig and the positions of the second filter or the third filter is shifted or damaged. Therefore, it is possible to reduce labor at the time of manufacturing each miniaturized component which requires careful work at the time of mounting the first filter later. Therefore, in another embodiment of the present disclosure, it is easy to achieve miniaturization of an optical module that includes three filters and multiplexes three lights having different wavelengths and emits multiplexed light.

### DETAILS OF EMBODIMENTS OF PRESENT DISCLOSURE

Next, an embodiment of the optical module of the present disclosure will be described with reference to the drawings. In the following drawings, the same or corresponding portions are denoted by the same reference numerals, and description thereof will not be repeated.

### First Embodiment

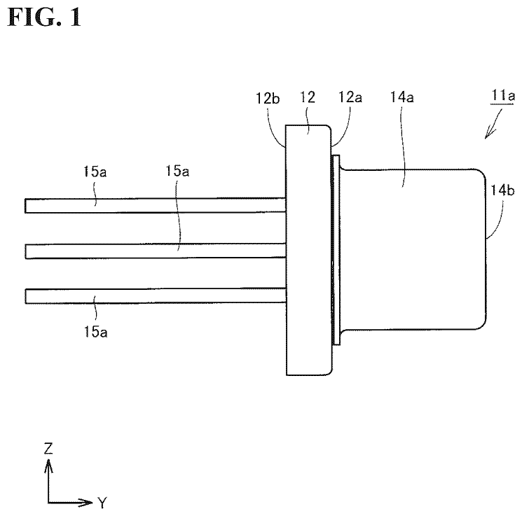

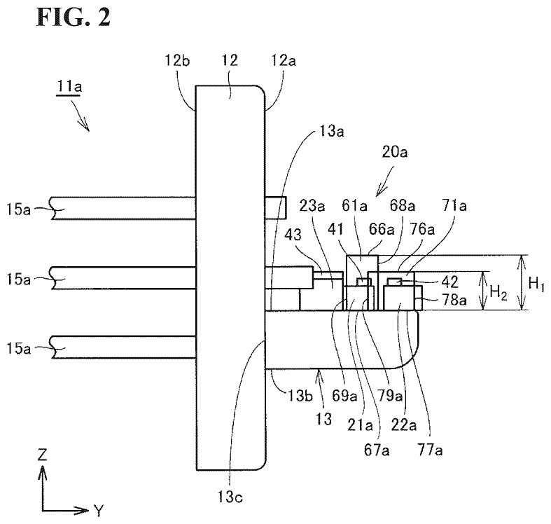

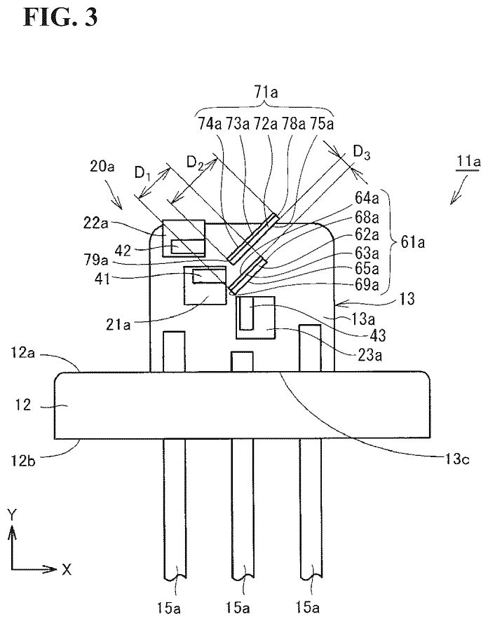

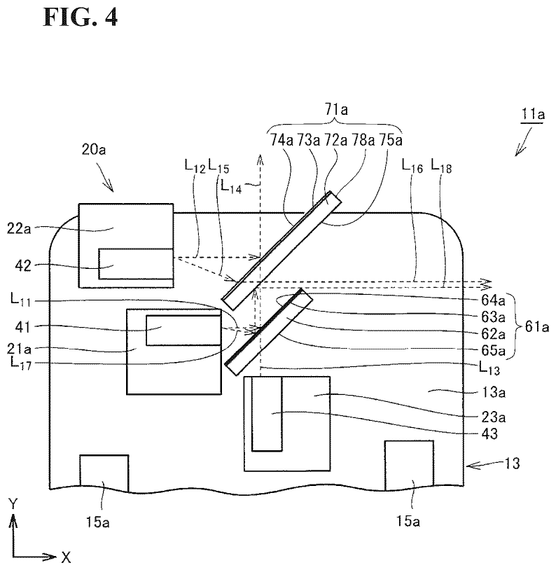

The configuration of the optical module in First Embodiment of the present disclosure will be described. FIG. 1 is a schematic side view showing an appearance of an optical module according to a first embodiment. FIG. 2 is a schematic side view of the optical module shown in FIG. 1 with the cap removed. FIG. 3 is a schematic plan view of the optical module shown in FIG. 2. FIG. 4 is an enlarged view showing a part of the optical module shown in FIG. 3.

Referring to FIGS. 1, 2, 3 and 4, an optical module 11a according to the first embodiment includes a substrate 12, a base member 13, a cap 14a, a plurality of a lead pins 15a, and a light forming unit 20a for forming light.

Substrate 12 has a circular plate shape. Substrate 12 includes a first main surface 12a of substrate 12 and a second main surface 12b differs from first main surface 12a of substrate 12. First main surface 12a and second main surface 12b are along the X-Z plane. The plurality of lead pins 15a penetrate from first main surface 12a to second main surface 12b. Each of the plurality of lead pins 15a is provided to extend in the Y direction. Each of the plurality of lead pins 15a is electrically connected to each component constituting light forming unit 20a, which will be described later, such as a first semiconductor light-emitting element 41, by wiring (not shown) or the like.

Base member 13 has a flat plate shape. Base member 13 includes a first surface 13a of base member 13, a second surface 13b differing from first main surface 13a of base member 13, and a third surface 13c connected to first surface 13a and second surface 13b. Each of first surface 13a and second surface 13b extends along the X-Y plane. Third surface 13c extends along the X-Z plane. Each component constituting light forming unit 20a is mounted on first surface 13a of base member 13. Base member 13 is disposed such that third surface 13c is in contact with first main surface 12a of substrate 12.

Cap 14a is a lid portion welded to substrate 12. Cap 14a is disposed on and in contact with first main surface 12a to cover light forming unit 20a and base member 13. That is, light forming unit 20a and base member 13 are disposed in a space surrounded by substrate 12 and cap 14a. In cap 14a, an emission window 14b through which light from light forming unit 20a passes is formed. In emission window 14b, a transmission plate that is made of glass and passes light is disposed.

Light forming unit 20a includes a first base block 21a, a second base block 22a, a third base block 23a, first semiconductor light-emitting element 41 configured to emit first light having a first wavelength, a second semiconductor light-emitting element 42 configured to emit second light having a second wavelength, a third semiconductor light-emitting element 43 configured to emit third light having a third wavelength, a first filter 61a, and a second filter 71a. The light formed by light forming unit 20a passes through emission window 14b and is emitted to the outside of optical module 11a.

Here, first semiconductor light-emitting element 41 is a green laser diode, second semiconductor light-emitting element 42 is a blue laser diode, and third semiconductor light-emitting element 43 is a red laser diode. Therefore, the first light having the first wavelength is green light, the second light having the second wavelength is blue light, and the third light having the third wavelength is red light.

First base block 21a, second base block 22a, and third base block 23a are disposed on first surface 13a of base member 13 at intervals. First semiconductor light-emitting element 41 is disposed on first base block 21a. Second semiconductor light-emitting element 42 is disposed on second base block 22a. Third semiconductor light-emitting element 43 is disposed on third base block 23a. First semiconductor light-emitting element 41, second semiconductor light-emitting element 42, and third semiconductor light-emitting element 43 are mounted on first surface 13a. The emitting direction of green light by first semiconductor light-emitting element 41 and the emitting direction of blue light by second semiconductor light-emitting element 42 are both the X direction. That is, an optical axis L₁₁ of the green light and an optical axis L₁₂ of the blue light are parallel to each other. The emitting direction of red light by third semiconductor light-emitting element 43 is the Y direction orthogonal to the emitting direction of green light by first semiconductor light-emitting element 41 and the emitting direction of blue light by second semiconductor light-emitting element 42. In other words, an optical axis L₁₃ of the red light is orthogonal to optical axis L₁₁ of the green light and optical axis L₁₂ of the blue light.

First filter 61a and second filter 71a are, for example, wavelength selective filters. Further, first filter 61a and second filter 71a are dielectric multilayer filters. The red light passes through first filter 61a, and first filter 61a reflects the green light. The red light and the green light passes through second filter 71a, and second filter 71a reflects the blue light.

First filter 61a has a flat plate shape. First filter 61a is rectangular when viewed in the thickness direction. The thickness direction of the filter is the direction along the X-Y plane. First filter 61a includes a transparent plate-shaped member 62a and a dielectric multilayer film 63a. Plate-shaped member 62a, for example, glass such as Pyrex (registered trade mark), silica, BK7 (registered trade mark), Tempax (registered trade mark) or the like is used. Dielectric multilayer film 63a is disposed on one of two surfaces of plate-shaped member 62a in the thickness direction. First filter 61a includes a first reflection surface 64a which is a first surface, a second surface 65a which differs from the first reflection surface, a third surface 66a, a fourth surface 67a, a fifth surface 68a, and a sixth surface 69a. Third surface 66a, fourth surface 67a, fifth surface 68a, and sixth surface 69a are connected to first reflection surface 64a and second surface 65a, respectively. Third surface 66a and fourth surface 67a are each along the X-Y plane. First reflection surface 64a and second surface 65a are parallel to each other. Third surface 66a and fourth surface 67a are parallel to each other. Fifth surface 68a and sixth surface 69a are parallel to each other. Fifth surface 68a is a plane perpendicular to each of first reflection surface 64a, second surface 65a, third surface 66a, and fourth surface 67a. Sixth surface 69a is a plane perpendicular to each of first reflection surface 64a, second surface 65a, third surface 66a, and fourth surface 67a. Dielectric multilayer film 63a is configured to include first reflection surface 64a. First reflection surface 64a is a surface that reflects the green light that is the first light having the first wavelength. That is, first filter 61a includes first reflection surface 64a that reflects green light that is first light. The red light, which is the third light having the third wavelength, passes through first filter 61a.

Second filter 71a has a flat plate shape. Second filter 71a is rectangular when viewed in the thickness direction. Second filter 71a includes a transparent plate-shaped member 72a and a dielectric multilayer film 73a. As the material of plate-shaped member 72a, the same material as that of plate-shaped member 62a is adopted. Dielectric multilayer film 73a is disposed on one of two surfaces of plate-shaped member 72a in the thickness direction. Second filter 71a includes a second reflection surface 74a which is a first surface, a second surface 75a which differs from the first surface, a third surface 76a, a fourth surface 77a, a fifth surface 78a, and a sixth surface 79a. Third surface 76a, fourth surface 77a, fifth surface 78a, and sixth surface 79a are connected to second reflection surface 74a and second surface 75a, respectively. Third surface 76a and fourth surface 77a are each along the X-Y plane. Second reflection surface 74a and second surface 75a are parallel to each other. Third surface 76a and fourth surface 77a are parallel to each other. Fifth surface 78a and sixth surface 79a are parallel to each other. Fifth surface 78a is a plane perpendicular to each of second reflection surface 74a, second surface 75a, third surface 76a, and fourth surface 77a. Sixth surface 79a is a plane perpendicular to each of second reflection surface 74a, second surface 75a, third surface 76a, and fourth surface 77a. Dielectric multilayer film 73a is configured to include second reflection surface 74a. Second reflection surface 74a is a surface that reflects the blue light that is second light having the second wavelength. That is, second filter 71a includes second reflection surface 74a that reflects blue light that is second light. The green light that is the first light and the red light that is the third light pass through second filter 71a.

First filter 61a and second filter 71a are mounted on first surface 13a. Specifically, first filter 61a is disposed so that fourth surface 67a of first filter 61a and first surface 13a face each other. Further, second filter 71a is disposed so that fourth surface 77a of second filter 71a and first surface 13a face each other. Each of first filter 61a and second filter 71a is attached to first surface 13a using an adhesive made of an ultraviolet curable resin or the like.

In a direction perpendicular to first surface 13a, the length of first filter 61a differs from the length of second filter 71a. Specifically, a length H₁ of first filter 61a, which is the interval between third surface 66a and fourth surface 67a of first filter 61a shown in FIG. 2, is longer than a length H₂ of second filter 71a, which is the interval between third surface 76a and fourth surface 77a of second filter 71a. In the embodiment of the present disclosure, first filter 61a and second filter 71a have the same rectangular shape when viewed in the thickness direction, first filter 61a is in a so-called horizontal state in which the long direction is attached to first surface 13a, and second filter 71a is in a so-called vertical state in which the short direction is attached to first surface 13a.

First filter 61a is disposed at a position on first reflection surface 64a where green light is reflected and red light is passed. Second filter 71a is disposed at a position on second reflection surface 74a where the blue light is reflected and the green light and the red light are passed. First reflection surface 64a of first filter 61a and second reflection surface 74a of second filter 71a are inclined with respect to an emitting direction of light emitted from first semiconductor light-emitting element 41 and second semiconductor light-emitting element 42, respectively. Specifically, first reflection surface 64a of first filter 61a and second reflection surface 74a of second filter 71a are inclined by 45° with respect to optical axis L₁₁ of green light emitted from first semiconductor light-emitting element 41 and optical axis L₁₂ of blue light emitted from second semiconductor light-emitting element 42, respectively. In the embodiment of the present disclosure, each of first reflection surface 64a of first filter 61a and second reflection surface 74a of second filter 71a is also inclined at 45° with respect to optical axis L₁₃ of red light emitted from third semiconductor light-emitting element 43. As a result, first filter 61a and second filter 71a multiplex light emitted from first semiconductor light-emitting element 41, second semiconductor light-emitting element 42, and third semiconductor light-emitting element 43. An optical axis L₁₄ of the multiplexed light is configured to pass through emission window 14b.

The light emitted from each of first semiconductor light-emitting element 41, second semiconductor light-emitting element 42, and third semiconductor light-emitting element 43 is spreading light. Among optical paths of light emitted from second semiconductor light-emitting element 42, an optical path diffused toward first semiconductor light-emitting element 41 is indicated by an optical path L₁₅. Here, first reflection surface 64a is located outside an optical path L₁₆ of the blue light emitted from second semiconductor light-emitting element 42 along optical path L₁₅ and passing through second filter 71a. In an embodiment of the present disclosure, when viewed in a direction perpendicular to first surface 13a, a length D₁ in a direction perpendicular to the thickness direction of first filter 61a is shorter than a length D₂ in a direction perpendicular to the thickness direction of second filter 71a. Thus, first reflection surface 64a is located outside optical path L₁₆ of the blue light emitted from second semiconductor light-emitting element 42 and passing through second filter 71a.

An interval D₃ between first filter 61a and second filter 71a is 0.1 mm to 0.3 mm. In the embodiment of the present disclosure, interval D₃ between first filter 61a and second filter 71a is the distance between first reflection surface 64a of first filter 61a and second surface 75a of second filter 71a.

Next, an example of a method of manufacturing optical module 11a will be briefly described. First, substrate 12 in which first base block 21a, second base block 22a, third base block 23a, first semiconductor light-emitting element 41, second semiconductor light-emitting element 42, and third semiconductor light-emitting element 43 are provided on base member 13 is prepared. Then, an adhesive is applied to predetermined positions on first surface 13a of base member 13, specifically, a desired position to which first filter 61a is attached and a desired position to which second filter 71a is attached. Then, first filter 61a and second filter 71a are attached on the adhesive, and first filter 61a and second filter 71a are mounted on first surface 13a of base member 13.

As for the attachment of first filter 61a and second filter 71a, second filter 71a having shorter length H₂ is attached, first. Here, the upper portion of second filter 71a, i.e., the region near third surface 76a is chucked and lifted by a jig so as to be sandwiched in the thickness direction of second filter 71a. Then, second filter 71a is attached to the attachment position of second filter 71a. Specifically, second filter 71a is attached such that the position of second reflection surface 74a is located at the intersection of the blue light emitted by second semiconductor light-emitting element 42, the green light emitted by first semiconductor light-emitting element 41 and reflected by first reflection surface 64a, and the red light emitted by third semiconductor light-emitting element 43. Then, the jig is opened in the thickness direction of second filter 71a to remove the jig from second filter 71a.

Next, first filter 61a having longer length H₁ is attached. Also in this case, the upper portion of first filter 61a, i.e., the region near third surface 66a is chucked and lifted by the jig so as to be sandwiched in the thickness direction of first filter 61a. Then, first filter 61a is attached to the attachment position of first filter 61a. Specifically, first filter 61a is attached such that the position of first reflection surface 64a is located at the intersection of the green light emitted by first semiconductor light-emitting element 41 and the red light emitted by third semiconductor light-emitting element 43. Then, the jig is opened in the thickness direction of first filter 61a to remove the jig from first filter 61a. Next, after the adhesive is cured, a plurality of lead pins 15a are attached to substrate 12, wiring to lead pins 15a is performed, and finally, cap 14a is attached. In this way, optical module 11a is assembled and manufactured.

In optical module 11a, length H₁ of first filter 61a differs from length H₂ of second filter 71a in the direction perpendicular to first surface 13a. In optical module 11a, one of first filter 61a and second filter 71a having a shorter length, i.e., second filter 71a in this case, is pinched and grasped by the jig, and the position is adjusted and mounted at a desired position on first surface 13a. Next, the filter having the longer length, i.e., first filter 61a in this case, is pinched and grasped by the jig, and the position thereof is adjusted and mounted at a desired position on first surface 13a. After mounting, when the jig is removed from first filter 61a, since length H₁ of the first filter mounted later is longer than length H₂ of second filter 71a mounted previously, the possibility of interference between second filter 71a mounted previously and the jig can be greatly reduced. Therefore, when first filter 61a is mounted later, it is possible to greatly reduce the possibility that second filter 71a mounted previously and the jig come into contact with each other and the position of second filter 71a mounted previously is shifted or damaged. Therefore, it is possible to reduce labor at the time of manufacturing each miniaturized component in which requires careful work at the time of mounting first filter 61a later. As a result, according to optical module 11a, miniaturization can be easily achieved.

In optical module 11a, second filter 71a includes second reflection surface 74a that reflects blue light that is second light emitted from second semiconductor light-emitting element 42. Here, with respect to second filter 71a, there is light that is not reflected by second reflection surface 74a but a part of the second light passes through second filter 71a although it is a small amount. When the partially passed blue light reaches first reflection surface 64a of first filter 61a and is reflected, it may become stray light having the same emission direction as the multiplexed light. Such a situation is undesirable because stray light may be emitted to the outside of optical module 11a.

According to optical module 11a, since first reflection surface 64a is located outside optical path L₁₆ of blue light emitted from second semiconductor light-emitting element 42 and passing through second filter 71a along optical path L₁₅, the possibility that the blue light passing through second filter 71a without being reflected by second reflection surface 74a reaches first reflection surface 64a can be reduced. Then, it is possible to reduce the possibility that the blue light passing through second filter 71a is reflected by first reflection surface 64a and becomes stray light. As a result, it is possible to reduce the possibility that stray light is emitted to the outside of optical module 11a.

In optical module 11a, interval D₃ between first filter 61a and second filter 71a is 0.1 mm to 0.3 mm. Such optical module 11a can reliably realize the minimization.

In optical module 11a, when viewed in the direction perpendicular to first surface 13a, length D₁ of first filter 61a in the direction perpendicular to the thickness direction is shorter than length D₂ of second filter 71a in the direction perpendicular to the thickness direction. Therefore, it is easy to locate the first reflection surface outside optical path L₁₆ of the blue light emitted from second semiconductor light-emitting element 42 along optical path L₁₅ and passing through second filter 71a. Therefore, it becomes easy to reduce the possibility of occurrence of stray light.

In the above embodiment, although first reflection surface 64a is located outside optical path L₁₆ of the light emitted from second semiconductor light-emitting element 42 along optical path L₁₅ and passing through second filter 71a, first reflection surface 64a may be located outside an optical path Lis of the light emitted from first semiconductor light-emitting element 41 along an optical path L₁₇ and reflected by second filter 71a. Among optical paths of light emitted from first semiconductor light-emitting element 41, the optical path diffuses to third semiconductor light-emitting element 43 is indicated by optical path L₁₇. That is, first reflection surface 64a may be located outside an optical path of at least either one of light emitted from second semiconductor light-emitting element 42 and passing through second filter 71a and light emitted from first semiconductor light-emitting element 41 and reflected by second filter 71a. In this way, it is possible to reduce the possibility that at least either one of the blue light which is the second light emitted from second semiconductor light-emitting element 42 and passing through second filter 71a without being reflected by second reflection surface 74a and the green light which is the first light emitted from first semiconductor light-emitting element 41 and reflected by a portion other than second reflection surface 74a of second filter 71a reaches first reflection surface 64a. Then, the possibility that the blue light emitted from second semiconductor light-emitting element 42 and passing through second filter 71a and the green light emitted from first semiconductor light-emitting element 41 and reflected by second filter 71a are reflected by first reflection surface 64a and become stray light can be reduced. As a result, it is possible to reduce the possibility that stray light is emitted to the outside of optical module 11a.

### Second Embodiment

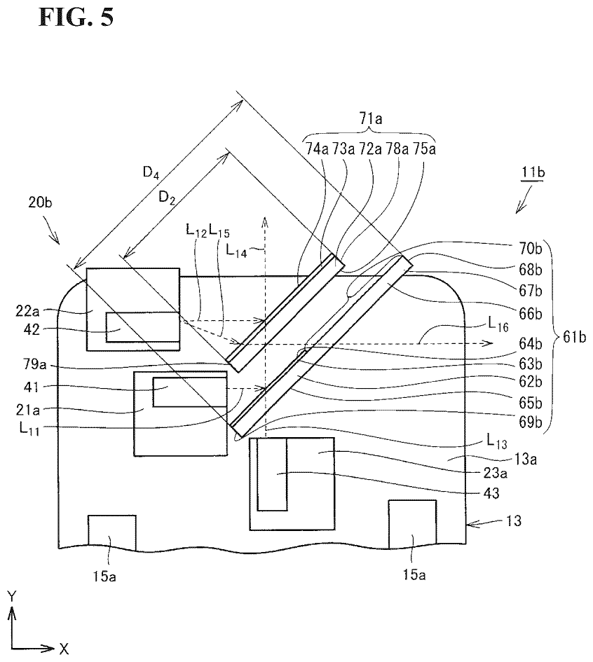

Next, a second embodiment which is another embodiment will be described. FIG. 5 is a schematic plan view showing an enlarged part of the optical module according to the second embodiment. The optical module according to the second embodiment differs from that according to the first embodiment in the configuration of the first filter.

Referring to FIG. 5, in a light forming unit 20b included in an optical module 11b of the second embodiment, when viewed in the direction perpendicular to first surface 13a (i.e., in the X-Y plane), a length D₄ of a first filter 61b in the direction perpendicular to the thickness direction is longer than length D₂ of second filter 71a in the direction perpendicular to the thickness direction. First filter 61b includes a first reflection surface 64b which is a first surface, a second surface 65b which differs from the first surface, a third surface 66b, a fourth surface 67b, a fifth surface 68b, and a sixth surface 69b. Length D₄ is a length from fifth surface 68b to sixth surface 69b. In addition, a dielectric multilayer film 63b included in first filter 61b is not provided on the entire surface of one of the two surfaces of a plate-shaped member 62b in the thickness direction, but is provided on a portion of the surface. In detail, first filter 61b includes plate-shaped member 62b and dielectric multilayer film 63b. Plate-shaped member 62b includes a region 70b in which dielectric multilayer film 63b is not formed at first reflection surface 64b side. Region 70b is a portion in which plate-shaped member 62b is disposed as it is, and light is passes through region 70b without being reflected.

According to this configuration, first reflection surface 64b can be located outside optical path L₁₆ of the blue light emitted from second semiconductor light-emitting element 42. Therefore, in region 70b, the possibility that the blue light emitted from second semiconductor light-emitting element 42 along optical path L₁₅ and passing through second filter 71a reaches first filter 61b and the reached light is reflected by first filter 61b can be reduced. Therefore, it is possible to reduce the possibility of occurrence of stray light.

### Third Embodiment

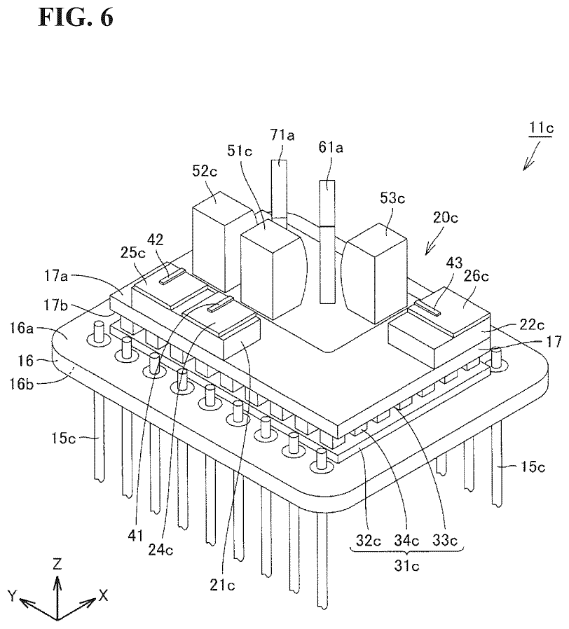

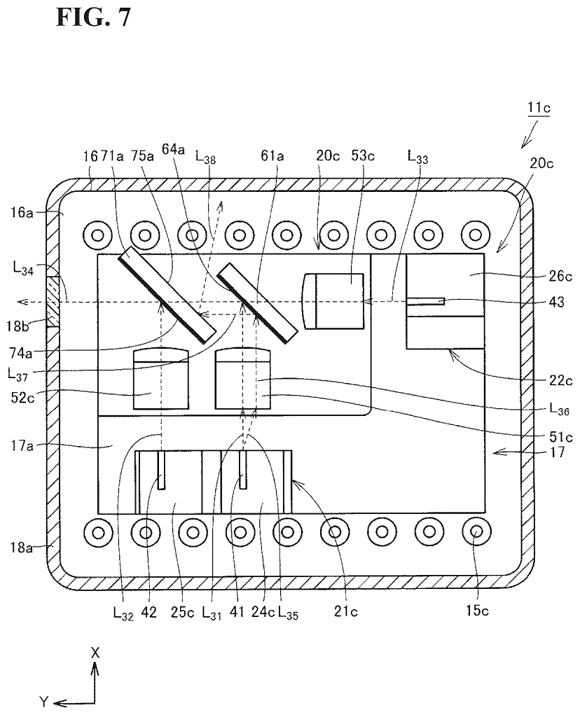

Next, a third embodiment which is still another embodiment will be described. FIG. 6 is a schematic perspective view showing an enlarged part of the optical module according to the third embodiment. FIG. 7 is a schematic plan view of the optical module shown in FIG. 6 cut along a plane including the cap. The optical module of the third embodiment differs from that of the first embodiment in that the optical module of the third embodiment includes a lens, a thermo-electric cooler (TEC) and the like. In FIG. 6, the cap included in the optical module is not shown.

Referring to FIGS. 6 and 7, an optical module 11c of the third embodiment includes a substrate 16, a base member 17, a cap 18a, a plurality of a lead pins 15c, and a light forming unit 20c for forming light.

Substrate 16 has a flat plate shape. Substrate 16 includes a first main surface 16a of substrate 16 and a second main surface 16b differing from first main surface 16a of substrate 16. First main surface 16a and second main surface 16b are along the X-Y plane. The plurality of lead pins 15c penetrate from first main surface 16a to second main surface 16b. Each of the plurality of lead pins 15c is provided to extend in the Z direction. Each of the plurality of lead pins 15c is electrically connected to each component constituting light forming unit 20c, which will be described later, such as first semiconductor light-emitting element 41.

Base member 17 has a flat plate shape. Base member 17 includes a first surface 17a of base member 17 and a second surface 17b differing from first surface 17a of base member 17. Each of first surface 17a and second surface 17b is along the X-Y plane. Each component constituting light forming unit 20c is mounted on first surface 17a of base member 17.

Optical module 11c includes a TEC 31c which is an electronic cooling module. TEC 31c includes a heat dissipation plate 32c, a heat absorption plate 33c, and a plurality of semiconductor pillars 34c. Each of heat dissipation plate 32c and heat absorption plate 33c has a flat plate shape. Heat dissipation plate 32c and heat absorption plate 33c are spaced apart from each other in the thickness direction of base member 17. The plurality of semiconductor pillars 34c are disposed at intervals. The plurality of semiconductor pillars 34c are attached such that one end is connected to heat dissipation plate 32c and the other end is connected to heat absorption plate 33c. TEC 31c is disposed between substrate 16 and base member 17. TEC 31c is disposed such that first main surface 16a of substrate 16 contacts heat dissipation plate 32c and second surface 17b of base member 17 contacts heat absorption plate 33c. By supplying a current to TEC 31c, the heat of base member 17 is transferred to substrate 16 side, and the temperature of base member 17 and light forming unit 20c are temperature-adjusted by cooling or the like.

Light forming unit 20c includes a first base block 21c, a second base block 22c, first semiconductor light-emitting element 41, second semiconductor light-emitting element 42, third semiconductor light-emitting element 43, first filter 61a, second filter 71a, a first lens 51c, a second lens 52c, and a third lens 53c. First lens 51c is disposed between first semiconductor light-emitting element 41 and first filter 61a when viewed in the thickness direction of base member 17. First lens 51c changes the spot size of the green light that is the first light emitted from the first semiconductor light-emitting element. In this case, first lens 51c changes the spreading light emitted from first semiconductor light-emitting element 41 to the collimate light. Second lens 52c is disposed between second semiconductor light-emitting element 42 and second filter 71a when viewed in the thickness direction of base member 17. Second lens 52c changes the spot size of the blue light that is the second light emitted from second semiconductor light-emitting element 42. In this case, second lens 52c changes the spreading light emitted from second semiconductor light-emitting element 42 to the collimate light. Third lens 53c is disposed between third semiconductor light-emitting element 43 and first filter 61a when viewed in the thickness direction of base member 17. Third lens 53c changes the spot size of red light that is the third light emitted from third semiconductor light-emitting element 43. In this case, third lens 53c changes the spreading light emitted from third semiconductor light-emitting element 43 to the collimate light. In this way, green light, blue light, and red light having a desired spot size can be emitted from optical module 11c. The light formed by light forming unit 20c passes through an emission window 18b and is emitted to the outside of optical module 11c.

First base block 21c and second base block 22c are respectively disposed on first surface 17a of base member 17 at intervals. A first sub-mount 24c and a second sub-mount 25c are disposed on first base block 21c. First semiconductor light-emitting element 41 is disposed on first sub-mount 24c. Second semiconductor light-emitting element 42 is disposed on second sub-mount 25c. A third sub-mount 26c is disposed on second base block 22c. Third semiconductor light-emitting element 43 is disposed on third sub-mount 26c. First semiconductor light-emitting element 41, second semiconductor light-emitting element 42, and third semiconductor light-emitting element 43 are mounted on first surface 13a. The emitting direction of green light by first semiconductor light-emitting element 41 and the emitting direction of blue light by second semiconductor light-emitting element 42 are both the X direction. That is, an optical axis L₃₁ of the green light and an optical axis L₃₂ of the blue light are parallel to each other. The emitting direction of red light by third semiconductor light-emitting element 43 is the Y direction orthogonal to the emitting direction of green light by first semiconductor light-emitting element 41 and the emitting direction of blue light by second semiconductor light-emitting element 42. That is, an optical axis L₃₃ of the red light is orthogonal to optical axis L₃₁ of the green light and optical axis L₃₂ of the blue light.

First filter 61a and second filter 71a are mounted on first surface 17a. Each of first filter 61a and second filter 71a is attached to first surface 17a using an adhesive made of an ultraviolet curable resin or the like.

In a direction perpendicular to first surface 17a, the length of first filter 61a differs from the length of second filter 71a. Specifically, the length of first filter 61a in the direction perpendicular to first surface 17a is longer than the length of second filter 71a in the direction perpendicular to first surface 17a.

First filter 61a is disposed at a position on first reflection surface 64a where green light is reflected and red light is passed. Second filter 71a is disposed at a position on second reflection surface 74a where blue light is reflected and green light and red light are passed. First reflection surface 64a of first filter 61a and second reflection surface 74a of second filter 71a are inclined with respect to an emitting direction of light emitted from first semiconductor light-emitting element 41 and second semiconductor light-emitting element 42, respectively. Specifically, first reflection surface 64a of first filter 61a and second reflection surface 74a of second filter 71a are inclined by 45° with respect to optical axis L₃₁ of green light emitted from first semiconductor light-emitting element 41 and optical axis L₃₂ of blue light emitted from second semiconductor light-emitting element 42, respectively. In the embodiment of the present disclosure, each of first reflection surface 64a of first filter 61a and second reflection surface 74a of second filter 71a is also inclined at 45° with respect to optical axis L₃₃ of red light emitted from third semiconductor light-emitting element 43. As a result, first filter 61a and second filter 71a multiplex light emitted from first semiconductor light-emitting element 41, second semiconductor light-emitting element 42, and third semiconductor light-emitting element 43. An optical axis L₃₄ of the multiplexed light is configured to pass through emission window 18b.

The light emitted from each of first semiconductor light-emitting element 41, second semiconductor light-emitting element 42, and third semiconductor light-emitting element 43 is spreading light. Among the optical paths of light emitted from first semiconductor light-emitting element 41, the optical path diffused toward third semiconductor light-emitting element 43 is indicated by an optical path L₃₅. The green light emitted from first semiconductor light-emitting element 41 along optical path L₃₅ proceeds along an optical path L₃₆ through first lens 51c, and is reflected by first reflection surface 64a of first filter 61a. Then, it proceeds along an optical path L₃₇. A small amount of light proceeding along optical path L₃₇ is reflected at second surface 75a of second filter 71a. Here, first reflection surface 64a is located outside an optical path L₃₈ of the green light emitted from first semiconductor light-emitting element 41 and reflected by second surface 75a of second filter 71a. In the embodiment of the present disclosure, when viewed in a direction perpendicular to first surface 17a, the length of first filter 61a in the direction perpendicular to the thickness direction is shorter than the length of second filter 71a in the direction perpendicular to the thickness direction. In this way, first reflection surface 64a is located outside optical path L₃₈ of the green light emitted from first semiconductor light-emitting element 41 and reflected by second surface 75a of second filter 71a.

Next, an example of a method of manufacturing optical module 11c will be briefly described. First, a TEC 31a is adhered on first main surface 16a of substrate 16. Thereafter, substrate 16 in which first base block 21c including first sub-mount 24c and second sub-mount 25c, second base block 22c including third sub-mount 26c, first semiconductor light-emitting element 41, second semiconductor light-emitting element 42, and third semiconductor light-emitting element 43 are provided on base member 17 is adhered on TEC 31a. Then, an adhesive is applied to predetermined positions on first surface 17a of base member 17, specifically, a desired position to which first filter 61a is attached and a desired position to which second filter 71a is attached. Then, first filter 61a and second filter 71a are attached on the adhesive, and first filter 61a and second filter 71a are mounted on first surface 17a of base member 17.

As for the attachment of first filter 61a and second filter 71a, second filter 71a is first attached. Here, the upper portion of second filter 71a is chucked and lifted by a jig so as to be sandwiched in the thickness direction of second filter 71a. Then, second filter 71a is attached to the attachment position of second filter 71a. Specifically, second filter 71a is attached such that the position of second reflection surface 74a is located at the intersection of the blue light emitted by second semiconductor light-emitting element 42, the green light emitted by first semiconductor light-emitting element 41 and reflected by first reflection surface 64a, and the red light emitted by third semiconductor light-emitting element 43. Then, the jig is opened in the thickness direction of second filter 71a to remove the jig from second filter 71a.

Next, first filter 61a is attached. Also in this case, the upper portion of first filter 61a is chucked and lifted by the jig so as to be sandwiched in the thickness direction of first filter 61a. Then, first filter 61a is attached to the attachment position of first filter 61a. Specifically, first filter 61a is attached such that the position of first reflection surface 64a is located at the intersection of the green light emitted by first semiconductor light-emitting element 41 and the red light emitted by third semiconductor light-emitting element 43. Then, the jig is opened in the thickness direction of first filter 61a to remove the jig from first filter 61a. Next, the adhesive is cured. Thereafter, the plurality of lead pins 15c are attached to substrate 16, wiring to lead pins 15c is performed, and finally cap 18a is attached. In this way, optical module 11c is assembled and manufactured.

Also in optical module 11c, in the direction perpendicular to first surface 17a, the length of first filter 61a differs from the length of second filter 71a. In optical module 11c, one of first filter 61a and second filter 71a having a shorter length, i.e., second filter 71a in this case, is pinched and grasped by the jig, and the position thereof is adjusted and mounted at a desired position on first surface 13a. Next, the filter having the longer length, i.e., first filter 61a in this case, is pinched and grasped by the jig, and the position thereof is adjusted and mounted at a desired position on first surface 13a. After the mounting, when the jig is removed from first filter 61a, since the length of first filter 61a mounted later is longer than the length of second filter 71a mounted previously, the possibility of interference between second filter 71a mounted previously and the jig can be greatly reduced. Therefore, when first filter 61a is mounted later, it is possible to greatly reduce the possibility that second filter 71a mounted previously and the jig come into contact with each other and the position of second filter 71a mounted previously is shifted or damaged. Therefore, it is possible to reduce labor at the time of manufacturing each miniaturized component in which requires careful work at the time of mounting first filter 61a later. As a result, according to optical module 11c, miniaturization can be easily achieved.

In optical module 11c, since first reflection surface 64a is located outside optical path L₃₈ of the green light emitted from first semiconductor light-emitting element 41 and reflected by second surface 75a of second filter 71a, it is possible to reduce the possibility that the green light reflected by second surface 75a other than second reflection surface 74a of second filter 71a, in this case, and proceeding along optical path L₃₈ reaches first reflection surface 64a. Then, the possibility that the green light reflected by second filter 71a is reflected by first reflection surface 64a and becomes stray light can be reduced. As a result, it is possible to reduce the possibility that stray light is emitted to the outside of optical module 11c.

### Fourth Embodiment

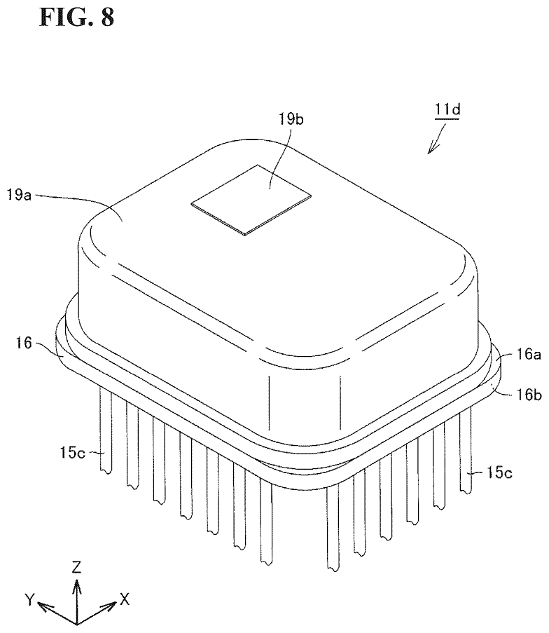

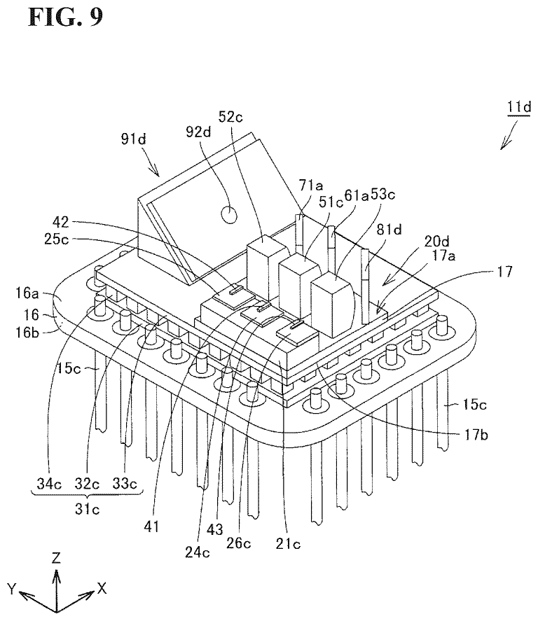

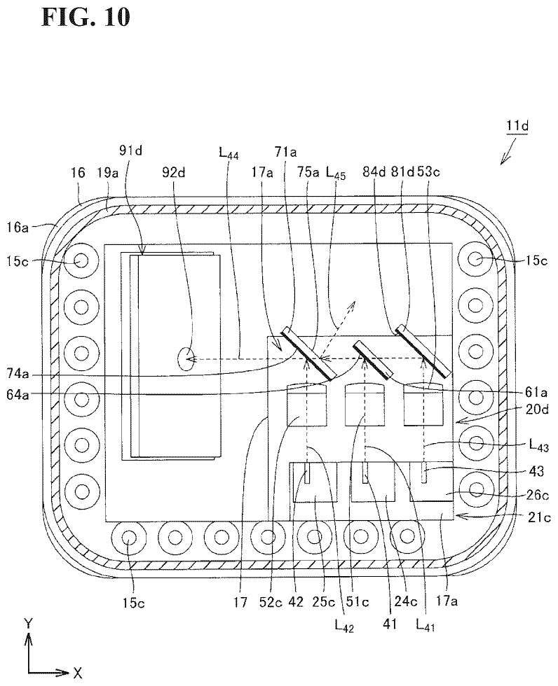

Next, a fourth embodiment which is still another embodiment will be described. FIG. 8 is a schematic perspective view of the optical module according to the fourth embodiment. FIG. 9 is a schematic perspective view of the optical module shown in FIG. 8 with the cap removed. FIG. 10 is a schematic plan view when the optical module shown in FIG. 8 is cut along a plane including the cap. The optical module according to the fourth embodiment differs from that according to the third embodiment in that it includes a mirror drive mechanism. In FIG. 9, the cap included in the optical module is not shown.

Referring to FIGS. 8, 9 and 10, an optical module 11d according to the fourth embodiment includes substrate 16, base member 17, a cap 19a provided with an emission window 19b, a plurality of lead pins 15c, TEC 31c, and a light forming unit 20d for forming light. Each component constituting light forming unit 20d is mounted on first surface 17a of base member 17.

Light forming unit 20d includes first base block 21c, first semiconductor light-emitting element 41, second semiconductor light-emitting element 42, third semiconductor light-emitting element 43, first filter 61a, second filter 71a, a third filter 81d, first lens 51c, second lens 52c, and third lens 53c. First filter 61a is disposed such that first reflection surface 64a is located outside an optical path L₄₅ of the green light emitted from first semiconductor light-emitting element 41 and reflected by second surface 75a of second filter 71a.

Third filter 81d is, for example, a wavelength selective filter. Third filter 81d is a dielectric multilayer filter. Third filter 81d reflects red light that is light having the third wavelength emitted from third semiconductor light-emitting element 43. Third filter 81d has a flat plate shape. Third filter 81d is rectangular when viewed in the thickness direction. Since the configuration of third filter 81d is the same as the configuration of second filter 71a except that the wavelength of light to be reflected is different, description thereof will be omitted.

Third lens 53c is disposed between third semiconductor light-emitting element 43 and third filter 81d when viewed in the thickness direction of base member 17. Third filter 81d is mounted on first surface 17a. Third filter 81d is attached beside first filter 61a in the X direction. In other words, first filter 61a is disposed between second filter 71a and third filter 81d in the X direction. In other words, when viewed in a direction perpendicular to first surface 17a of base member 17, first filter 61a is disposed between second filter 71a and third filter 81d. Third filter 81d is attached to first surface 17a using an adhesive made of an ultraviolet curable resin or the like.

First base block 21c is disposed on first surface 17a of base member 17. First sub-mount 24c, second sub-mount 25c, and third sub-mount 26c are disposed on first base block 21c. First semiconductor light-emitting element 41 is disposed on first sub-mount 24c. Second semiconductor light-emitting element 42 is disposed on second sub-mount 25c. Third semiconductor light-emitting element 43 is disposed on third sub-mount 26c. First semiconductor light-emitting element 41, second semiconductor light-emitting element 42, and third semiconductor light-emitting element 43 are mounted on first surface 13a. The emitting direction of green light by first semiconductor light-emitting element 41, the emitting direction of blue light by second semiconductor light-emitting element 42, and the emitting direction of red light by third semiconductor light-emitting element 43 are all the X direction. That is, an optical axis L₄₁ of the green light, an optical axis L₄₂ of the blue light, and an optical axis L₄₃ of the red light are parallel to each other.

In a direction perpendicular to first surface 17a, the length of first filter 61a differs from the length of third filter 81d. Specifically, the length of first filter 61a in the direction perpendicular to first surface 17a is longer than the length of third filter 81d in the direction perpendicular to first surface 17a. Also in the embodiment of the present disclosure, the length of first filter 61a in the direction perpendicular to first surface 17a is longer than the length of second filter 71a in the direction perpendicular to first surface 17a. That is, in the direction perpendicular to first surface 17a, the length of first filter 61a is longer than the length of second filter 71a and the length of third filter 81d.

Third filter 81d is disposed at a position where red light is reflected on a third reflection surface 84d. Third reflection surface 84d of third filter 81d is inclined with respect to an emitting direction of light emitted from third semiconductor light-emitting element 43. Specifically, third reflection surface 84d of third filter 81d is inclined by 45° with respect to optical axis L₄₃ of the red light emitted from third semiconductor light-emitting element 43. As a result, first filter 61a and second filter 71a multiplex light emitted from first semiconductor light-emitting element 41, second semiconductor light-emitting element 42, and third semiconductor light-emitting element 43.

Light forming unit 20d included in optical module 11d includes a mirror drive mechanism 91d. Mirror drive mechanism 91d includes a mirror 92d that reflects the light multiplexed by second filter 71a. Mirror drive mechanism 91d is disposed on TEC 31c. Specifically, mirror drive mechanism 91d is disposed so that light of an optical axis L₄₄ multiplexed by second filter 71a reflects on oscillating mirror 92d and the reflected light could be emitted from emission window 19b. Mirror drive mechanism 91d scans and emits light multiplexed by second filter 71a. That is, light formed by light forming unit 20d passes through emission window 19b and is emitted to the outside of optical module 11d. Optical module 11d scans light obtained by multiplexing green light which is first light, blue light which is second light, and red light which is third light along a desired path, thereby drawing a character, a figure, or the like.

Also in optical module 11d, the length of first filter 61a differs from the length of second filter 71a in the direction perpendicular to first surface 17a. In optical module 11d, one of first filter 61a, second filter 71a and third filter 81d having a shorter length, in this case, second filter 71a or third filter 81d, for example, second filter 71a is pinched and grasped by the jig, and the position of second filter 71a is adjusted and mounted at a desired position on first surface 13a. Next, third filter 81d is pinched and grasped, and the position thereof is adjusted and mounted at a desired position on first surface 13a. In this case, after mounting, when the jig is removed from third filter 81d, since the interval between third filter 81d mounted later and second filter 71a is large, the possibility of interference between second filter 71a mounted previously and the jig can be greatly reduced. Next, the filter having the longer length, i.e., first filter 61a in this case, is pinched and grasped by the jig, and the position thereof is adjusted and mounted at a desired position on first surface 13a. After mounting, when the jig is removed from first filter 61a, since the length of first filter 61a mounted later is longer than the lengths of second filter 71a and third filter 81d mounted previously, the possibility of interference between the jig and second filter 71a and third filter 81d mounted previously can be greatly reduced. Therefore, when first filter 61a is mounted later, it is possible to greatly reduce the possibility that second filter 71a and third filter 81d mounted previously come into contact with the jig and second filter 71a or third filter 81d mounted previously is shifted or damaged. Therefore, it is possible to reduce labor at the time of manufacturing each miniaturized component in which requires careful work at the time of mounting first filter 61a. As a result, according to optical module 11d, miniaturization can be easily achieved.

In optical module 11d, since first reflection surface 64a is located outside optical path L₄₅ of the green light emitted from first semiconductor light-emitting element 41 and reflected by second surface 75a of second filter 71a, it is possible to reduce the possibility that the green light emitted from first semiconductor light-emitting element 41 and reflected by second surface 75a other than second reflection surface 74a of second filter 71a, in this case, reaches first reflection surface 64a. Then, the possibility that the green light emitted from first semiconductor light-emitting element 41 and reflected by second filter 71a is reflected by first reflection surface 64a and becomes stray light. As a result, it is possible to reduce the possibility that stray light is emitted to the outside of optical module 11d.

### Other Embodiments

Although in the above-described embodiment, the optical module includes the first semiconductor light-emitting element, the second semiconductor light-emitting element, and the third semiconductor light-emitting element, the optical module may not include the third semiconductor light-emitting element. In this case, the combination of the first semiconductor light-emitting element and the second semiconductor light-emitting element may be light having different wavelengths.

It should be understood that the embodiments disclosed herein are illustrative in all respects and are not restrictive in any respect. The scope of the present disclosure is defined not by the above description but by the claims, and is intended to include all modifications within the meaning and scope equivalent to the claims.

### REFERENCE SIGNS LIST

11a, 11b, 11c, 11d optical module, 12,16 substrate, 12a, 16a first main surface, 12b, 16b second main surface, 13,17 base member, 13a, 17a first surface, 13b, 17b, 65a, 65b, 75a second surface, 13c, 66a, 66b, 76a third surface, 14a, 18a, 19a cap, 14b, 18b, 19b emission window, 15a, 15c lead pin, 20a, 20b, 20c, 20d light forming unit, 21a, 21c first base block, 22a, 22c second base block, 23a third base block, 24c first sub-mount, 25c second sub-mount, 26c third sub-mount, 31c TEC, 32c heat dissipation plate, 33c heat absorption plate, 34c semiconductor pillar, 41 first semiconductor light-emitting element, 42 second semiconductor light-emitting element, 43 third semiconductor light-emitting element, 51c first lens, 52c second lens, 53c third lens, 61a, 61b first filter 62a, 62b, 72a plate-shaped member, 63a, 63b, 73a dielectric multilayer film, 64a, 64b first reflection surface, 67a, 67b, 77a fourth surface, 68a, 68b, 78a fifth surface, 69a, 69b, 79a sixth surface, 70b region, 71a second filter, 74a second reflection surface, 81d third filter, 84d third reflection surface, 91d mirror drive mechanism, 92d mirror, D₁, D₂, D₄, H₁, H₂ length, D₃ interval, L₁₁, L₁₂, L₁₃, L₁₄, L₃₁, L₃₂, L₃₃, L₃₄, L₄₁, L₄₂, L₄₃, L₄₄ optical axis, L₁₅, L₁₆, L₁₇, L₁₈, L₃₅, L₃₆, L₃₇, L₃₈, L₄₅ optical path

1. An optical module comprising:
a base member including a first surface;
a first semiconductor light-emitting element mounted on the first surface and configured to emit first light having a first wavelength;
a first filter mounted on the first surface and including a first reflection surface configured to reflect the first light;
a second semiconductor light-emitting element mounted on the first surface and configured to emit second light having a second wavelength differing from the first wavelength; and
a second filter mounted on the first surface and including a second reflection surface configured to reflect the second light,
wherein the first light and the second light are multiplexed when the first light reflected by the first reflection surface passes through the second filter and the second reflection surface reflects the second light, and
wherein a length of the first filter differs from a length of the second filter in a direction perpendicular to the first surface.

2. The optical module according to claim 1, wherein the first reflection surface is located outside an optical path of at least either one of light emitted from the second semiconductor light-emitting element and passing through the second filter and light emitted from the first semiconductor light-emitting element and reflected by the second filter.

3. The optical module according to claim 1, wherein an interval between the first filter and the second filter is 0.1 mm to 0.3 mm.

4. The optical module according to claim 1, further comprising a lens configured to change a spot size of the first light emitted from the first semiconductor light-emitting element or the second light emitted from the second semiconductor light-emitting element.

5. The optical module according to claim 1, further comprising a mirror drive mechanism including a mirror configured to reflect light multiplexed by the second filter, the mirror drive mechanism being configured to scan and emit the light multiplexed by the second filter.

6. The optical module according to claim 1,
wherein the first filter and the second filter each have a plate shape, and
wherein, when viewed in the direction perpendicular to the first surface, a length of the first filter in a direction perpendicular to a thickness direction of the first filter is shorter than a length of the second filter in a direction perpendicular to a thickness direction of the second filter.

7. An optical module comprising:
a base member including a first surface;
a first semiconductor light-emitting element mounted on the first surface and configured to emit first light having a first wavelength;
a first filter mounted on the first surface and including a first reflection surface configured to reflect the first light;
a second semiconductor light-emitting element mounted on the first surface and configured to emit second light having a second wavelength differing from the first wavelength;
a second filter mounted on the first surface and including a second reflection surface configured to reflect the second light;
a third semiconductor light-emitting element mounted on the first surface and configured to emit third light having a third wavelength differing from the first wavelength and the second wavelength; and
a third filter mounted on the first surface and including a third reflection surface configured to reflect the third light,
wherein, when viewed in a direction perpendicular to the first surface, the first filter is disposed between the second filter and the third filter,
wherein the first light, the second light, and the third light are multiplexed when the first light reflected by the first reflection surface passes through the second filter, the second reflection surface reflects the second light, and the third light reflected by the third reflection surface passes through the first filter and the second filter, and
wherein, in the direction perpendicular to the first surface, a length of the first filter is longer than a length of the second filter and a length of the third filter.
